(19) United States
(12) Patent Application Publication
(10) Pub. No.: US 2025/0309837 A1
(43) Pub. Date: Oct. 2, 2025

(54) DIODE-BASED BIAS CIRCUIT

(71) Applicant: Qorvo US, Inc., Greensboro, NC (US)

(72) Inventor: Bruce John Tesch, Melbourne, FL (US)

(21) Appl. No.: 18/969,676

(22) Filed: Dec. 5, 2024

Related U.S. Application Data
(60) Provisional application No. 63/570,946, filed on Mar. 28, 2024.

(51) Int. Cl. H03F 3/193; H04B 1/40

(52) U.S. Cl. CPC H03F 3/193; H04B 1/40; H03F 2200/294; H03F 2200/451

(57) ABSTRACT

Diode-based bias circuits are disclosed. In one aspect, a bias circuit for a low noise amplifier (LNA) has differential or paired transistors wrapped around a paired diode-based core circuit. A voltage difference between the paired diodes creates a voltage across a resistor in the core circuit. The current through the diodes creates a current in the paired transistors to provide a feedback loop that allows for fast settling by avoiding any high impedance nodes in the loop while also keeping the supply voltage requirements low.

### PRIORITY APPLICATION

The present application is related to U.S. Provisional Patent Application Ser. No. 63/570,946 filed on Mar. 28, 2024, and entitled “DIODE-BASED BIAS CIRCUIT,” the contents of which are incorporated herein by reference in its entirety.

### BACKGROUND

### I. Field of the Disclosure

The technology of the disclosure relates generally to bias circuits for low noise amplifiers and, particularly, to diode-based bias circuits.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find more bandwidth through which data may be sent to and received from wireless communication devices. This pressure has resulted in the evolution of various wireless standards with a trend towards higher frequencies and more complicated encoding schemes. These wireless standards put pressure on the hardware to accommodate fast switching between transmission and reception. This pressure provides room for innovation.

### SUMMARY

Aspects disclosed in the detailed description include diode-based bias circuits. In particular, aspects of the present disclosure contemplate a bias circuit for a low noise amplifier (LNA) that has a differential or paired transistors wrapped around a paired diode-based core circuit. A voltage difference between the paired diodes creates a voltage across a resistor in the core circuit. The current through the diodes creates a current in the paired transistors to provide a feedback loop that allows for fast settling by avoiding any high-impedance nodes in the loop while also keeping the supply voltage requirements low. The same circuits can be used with slight modifications to make stable band gap reference voltage sources.

In this regard, in one aspect, a bias circuit is disclosed. The bias circuit includes a core circuit comprising a first diode, a second diode paired to the first diode, and a resistor, where a voltage difference between the first diode and the second diode appears across the resistor. The bias circuit also includes a pair of differential field effect transistors (FETs), each of the pair coupled to a respective one of the first and second diodes, at least one of the pair configured to create a feedback signal to an output FET.

In another aspect, a wireless transceiver is disclosed. The wireless transceiver includes a receiver chain comprising an LNA and a bias circuit for the LNA. The bias circuit comprising a core circuit comprising a first diode, a second diode paired to the first diode, and a resistor, where a voltage difference between the first diode and the second diode appears across the resistor. The bias circuit also includes a pair of differential FETs, each of the pair coupled to a respective one of the first and second diodes, at least one of the pair configured to create a feedback signal to an output FET coupled to the LNA.

In another aspect, a method of controlling a bias circuit is disclosed. The method includes providing a supply voltage below 1.5 volts to a pair of diodes in such a manner that a voltage difference therebetween appears across a resistor and coupling a differential pair of transistors to the pair of diodes to create a feedback signal that causes the bias circuit to settle in less than 250 nanoseconds.

### BRIEF DESCRIPTION OF THE DRAWINGS

FIG. 1 is a block diagram of a receiver chain with a low noise amplifier having a bias circuit;

FIG. 2A is a circuit diagram of a first aspect of a diode-based bias circuit;

FIG. 2B is a circuit diagram of a variation on the first aspect with improved performance;

FIG. 3 is a circuit diagram of a second aspect of a diode-based bias circuit that has a higher loop-gain than the circuit of FIG. 2A;

FIG. 4 is a circuit diagram of a third aspect of a diode-based circuit that preserves the higher loop-gain of the circuit of FIG. 2A while also providing better supply rejection;

FIG. 5 is a circuit diagram of a band gap voltage reference circuit based on the diode-based bias circuit of FIG. 2A;

FIG. 6 is a circuit diagram of a band gap voltage reference circuit based on the diode-based bias circuit of FIG. 3;

FIG. 7 is a circuit diagram of a band gap voltage reference circuit based on the diode-based bias circuit of FIG. 4;

FIG. 8 is a flowchart illustrating an exemplary process for providing a fast-settling, low supply voltage bias circuit that can be implemented without bipolar technologies; and

FIG. 9 is a block diagram of a receiver, which may include the bias circuit of FIGS. 2A-4 or the band gap voltage reference circuit of FIGS. 5-8, according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element, or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, bias circuitry, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include diode-based bias circuits. In particular, aspects of the present disclosure contemplate a bias circuit for a low noise amplifier (LNA) that has a differential or paired transistors wrapped around a paired diode-based core circuit. A voltage difference between the paired diodes creates a voltage across a resistor in the core circuit. The current through the diodes creates a current in the paired transistors to provide a feedback loop that allows for fast settling by avoiding any high-impedance nodes in the loop while also keeping the supply voltage requirements low. The same circuits can be used with slight modifications to make stable band gap reference voltage sources.

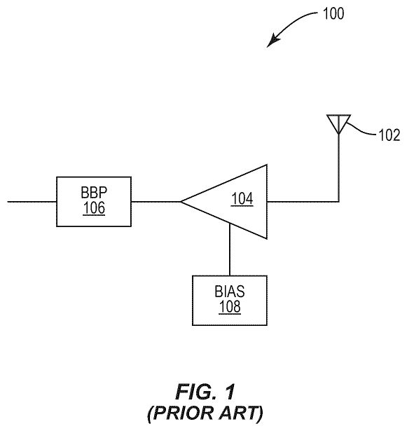

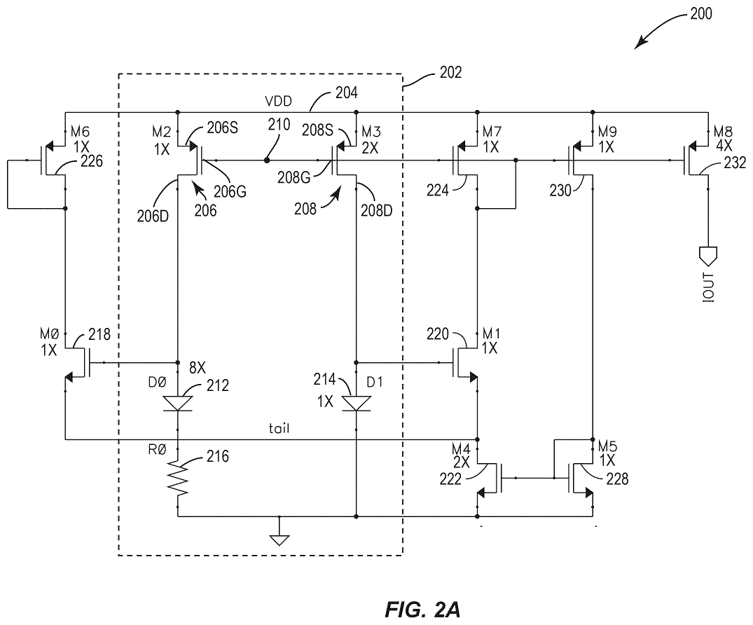

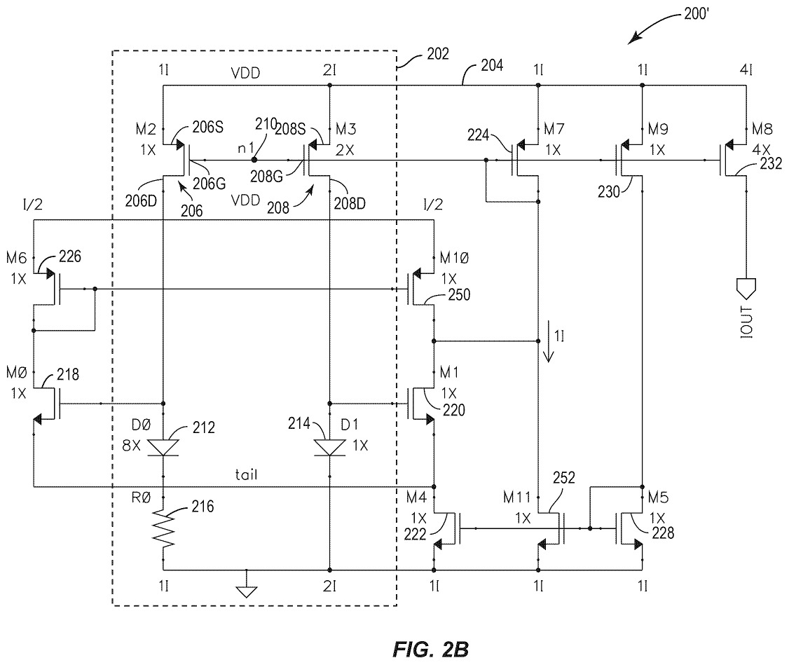

Before addressing aspects of the present disclosure, a brief overview of a receiver is provided with reference to FIG. 1, along with some of the design challenges for a bias circuit used in the receiver. A discussion of aspects of the present disclosure begins below with reference to FIG. 2A.

In this regard, FIG. 1 illustrates a receiver 100 that is configured to receive wireless signals at an antenna 102. The received signals are amplified by a low noise amplifier (LNA) 104 before being passed to a baseband processor (BBP) 106 (perhaps through an intermediate band processor that down converts the signals) as is well understood. The LNA 104 may be connected to and biased by a bias circuit 108.

Wireless receiver designers are being asked to have bias circuits that operate at increasingly lower voltages, with, as of this writing, a common supply voltage being under 1.5 volts and, more commonly, 1.2 volts plus or minus ten percent (±10%). Additionally, there is a desire to be able to have homogenous fabrication technologies used to simplify the process of making receivers. Additionally, the current wireless protocols involve frequent switching between transmit and receive modes. Each time such a switch back to receive mode occurs, the LNA is enabled and takes time to settle, in part based on the speed of the bias circuit. The switching frequency means that wireless receiver designers are being asked to enable in times less than 500 nanoseconds.

In the past, there have been various approaches used for bias circuits. However, to date, such approaches have failed to meet one or the other of the design criteria. For example, prior solutions may require higher supply voltages to meet enable times or may have high impedance nodes in a feedback loop requiring compensation capacitors, making the enable time too slow to meet requirements. Other solutions that include field effect transistors (FETs) mixed with bipolar junction transistors (BJTs) operating at different current densities might meet the requirements but are commercially impractical on mixed silicon on insulator (SOI) complementary metal oxide semiconductor (CMOS) devices. Thus, to date, no bias circuit has been able to meet the 1.2-volt power supply requirements and the 500 ns enable time while being CMOS fabrication friendly.

Exemplary aspects of the present disclosure use a core circuit where a voltage difference between two diodes appears across a resistor. This core circuit is stable and predictable over process, voltage, and temperature (PVT) variations and is proportional to absolute temperature (PTAT). The use of diodes also avoids reliance on metal oxide semiconductor FETs (MOSFETs), which may be unpredictable over PVT. This solution also does not rely on an operational amplifier (op-amp) that may have high-impedance nodes in a feedback loop where the op-amp is used to reduce supply voltage requirements at the expense of enable times. While this introduction explains what the bias circuit of the present disclosure is not, the following Figures provide a better explanation for what the bias circuit is.

In this regard, FIG. 2A illustrates a circuit diagram of a first aspect of a bias circuit 200. Omitted from FIG. 2A (and other Figures) is a start-up circuit. It should be appreciated that start-up circuits are well-known and not central to the present disclosure. The bias circuit 200 includes a core circuit 202 that couples to a supply voltage rail 204 that has supply voltage VDD thereon. The supply voltage VDD is provided to the respective sources 206S, 208S of PFETs 206 (M2), 208 (M3). Gates 206G, 208G are both connected to node 210. Drains 206D, 208D are coupled to respective diodes 212 (D0), 214 (D1). In an exemplary aspect, there is an 8:1 ratio between the diode 212 and the diode 214 (as evidenced by the 8x and 1x reference in FIG. 2A). While an 8:1 ratio is used herein, it should be appreciated that other ratios may also be used without departing from the present disclosure. A voltage difference between the diodes 212, 214 appears across a resistor (RO) 216. The PFETs 206, 208 act as a current mirror, where, assuming the PFETs are the same size, there is a 1:2 ratio (as further indicated by the 1x proximate PFET 206 and the 2x proximate the PFET 208). It should be appreciated that other current ratios could be used without departing from the present disclosure. Other current mirror ratios are similarly indicated in the Figures.

The core circuit 202 is sandwiched between differential FETs 218 (M0), 220 (M1), which, in an exemplary aspect, are NFETs. This differential pair is biased by the tail current source, namely FET 222 (M4). One-half of the tail current flows into diode-connected FET 224 (M7) that controls the node 210. This current flow also closes a feedback loop. The other half of this tail current from FET 222 flows into diode-connected FET 226 (M6), essentially not using half of the loop-gain, resulting in a better phase margin. Current in the FET 222 is mirrored into diode-connected FET 228 (M5) (at a 2:1 ratio), which together with FET 230 (M9) form a self-bias loop. Again, different current ratios may be used without departing from the present disclosure. The bias current for the LNA (not shown) is output from the FET 232 (M8).

It should be appreciated that ΔVds of each of the PFETs 206, 208, 230, and 232 track the supply voltage and thus provide excellent supply rejection, thereby avoiding any need to cascode any of the FETs just mentioned. The bias circuit 200 will operate properly over PVT with a supply voltage as low as 1.08 V. However, as noted, the half-tail current through the FET 218 does not contribute to loop-gain, thereby improving the phase margin. The bias circuit may meet the 500 ns requirement and, in fact, may be less than 250 ns and may further be around 200 ns or less.

FIG. 2B illustrates a similar bias circuit 200′, which adds FET 250 to form a current mirror with FET 226. Additionally, a FET 252 is added into the current mirror formed by FETs 222, 228. The current ratio for the FET 222 is also reduced. This doubles the loop-gain, resulting in greater accuracy without requiring any additional Vdd headroom. Excellent power supply rejection is also maintained. Further, this structure avoids any high-impedance nodes in the feedback loop. The bias circuit may meet the 500 ns requirement and, in fact, may be less than 250 ns and may further be around 200 ns or less.

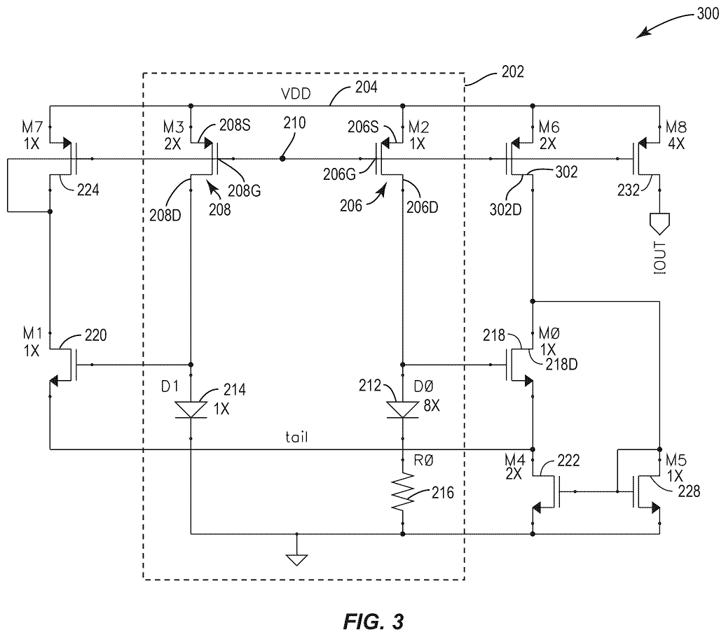

FIG. 3 illustrates a bias circuit 300 that does use the other half-tail current. The core circuit 202 remains the same. Note that the relative positions of diodes 212, 214 and FETs 206, 208, 218, 220 have been swapped. Many of the elements remain the same and are not discussed again, but FET 302 replaces FET 226 and is no longer diode-connected. Likewise, instead of FET 228 connected to FET 230, the FET 228 now is connected to the drain 218D of the FET 218 and drain 302D of the FET 302.

While this provides a higher loop-gain (and thus better accuracy) and also functions with a supply voltage of 1.08 V, ΔVds of FET 218 no longer tracks the supply voltage (because FET 228 fixes the drain voltage of the FET 218 at the diode-connected value for the FET 228 (e.g., 700-800 mV)) resulting in degraded supply rejection. While cascode devices could be added to various ones of the FETs of bias circuit 300 to improve supply rejections, the addition of such cascoded devices adds area, complexity and may result in higher supply voltage requirements. The bias circuit may meet the 500 ns requirement and, in fact, may be less than 250 ns and may further be around 200 ns or less.

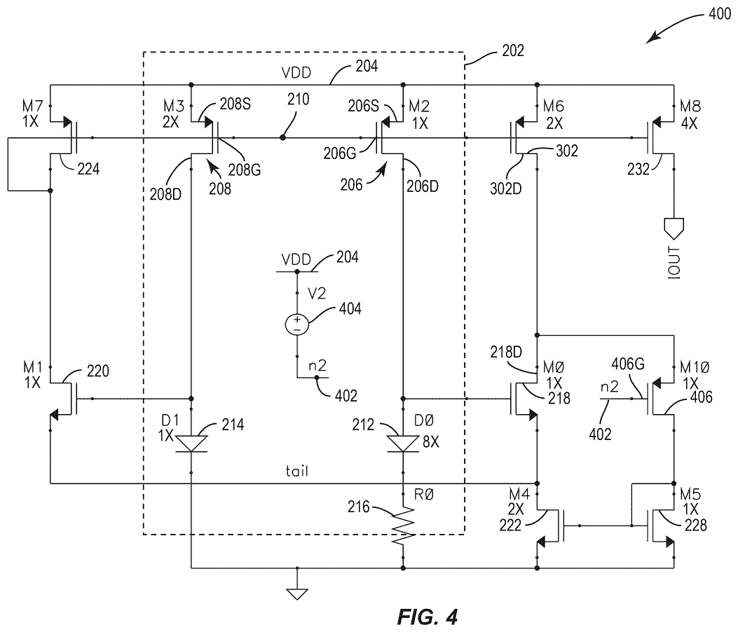

A third option for a bias circuit is provided with reference to FIG. 4. The bias circuit 400 builds on the bias circuit 300 but allows Vds of the FET 218 to track the supply voltage. An additional node 402 is added with a voltage source 404 that is equal to the supply voltage minus twice the gate-source voltage (i.e., Vdd−2 Vgs). The node 402 is connected to a gate 406G of a FET 406 that connects the FET 228 to the FET 218. The FET 406 adds Vgs to go with Vgs of the FET 228, meaning that ΔVDD is now present at drain 218D (as denoted by node n2 being present at both locations), meaning that the FET 218 now tracks the supply voltage. There may be some need to increase VDD to 1.5 V for this aspect, but this supply voltage is still lower than prior solutions. The bias circuit may meet the 500 ns requirement and, in fact, may be less than 250 ns and may further be around 200 ns or less.

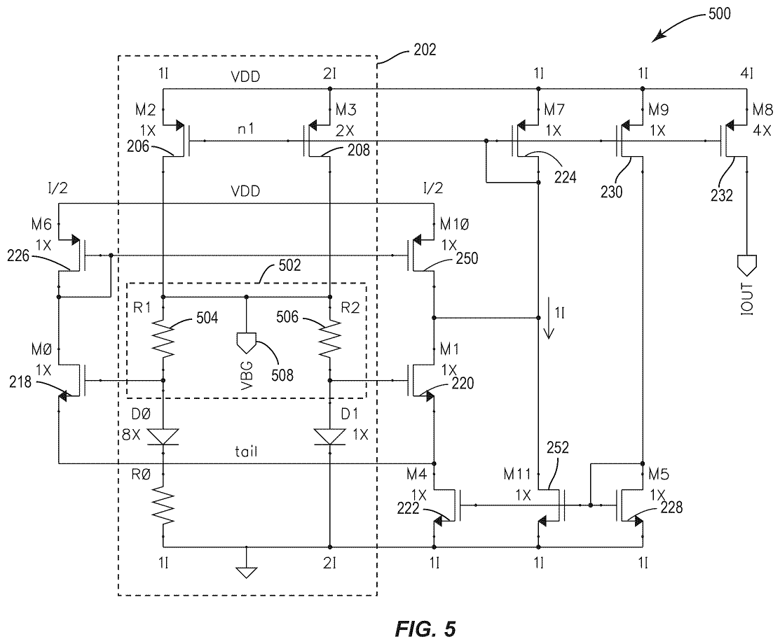

While aspects of the present disclosure are well suited for use to provide a fast-settling bias circuit for an LNA, the present disclosure also finds use in providing a band gap voltage reference, as illustrated in FIGS. 5-7. In each case a band gap circuit 502 is added to one of the circuits 200′, 300, 400. Thus, in FIG. 5, a circuit 500 is, in essence, the bias circuit 200′ of FIG. 2B with band gap circuit 502 added. The band gap circuit 502 includes two resistors 504, 506 coupled by a short to provide band gap reference 508. While not illustrated, the band gap circuit 502 could also be added to the bias circuit 200 of FIG. 2A.

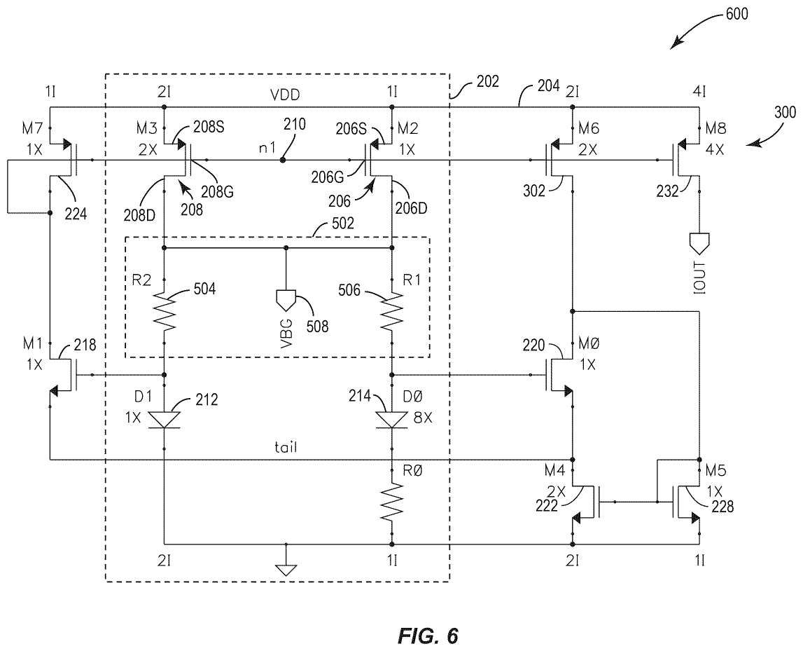

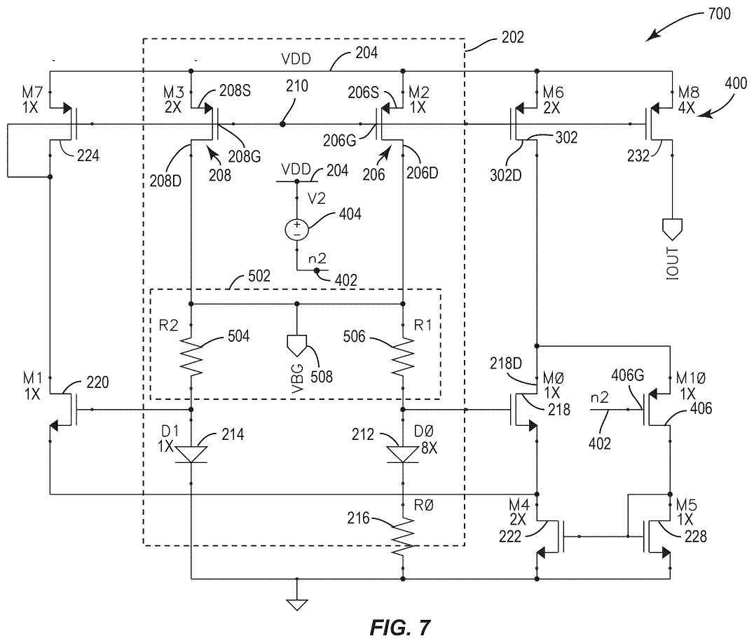

Similarly, FIG. 6 illustrates a circuit 600 that is bias circuit 300 with the band gap circuit 502 added, and FIG. 7 illustrates a circuit 700 that is bias circuit 400 with the band gap circuit 502 added.

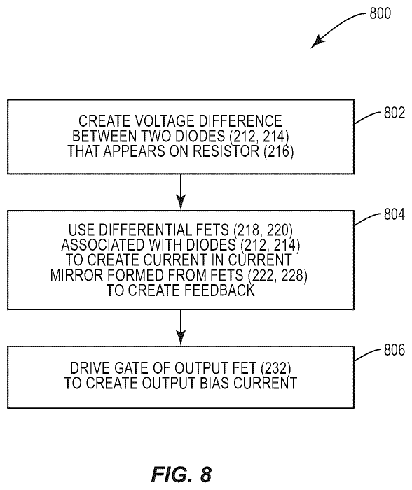

A process 800 for using the bias circuits of the present disclosure is provided with reference to FIG. 8. The process 800 begins by creating a voltage difference between the two diodes 212, 214 that appears on the resistor 216 (block 802). Differential FETs 218, 220 associated with the diodes 212, 214 create current in a current mirror formed from FETs 222, 228 to create a feedback signal (block 804). The feedback helps drive a gate of an output FET 232 to create an output bias current (block 806).

The diode-based bias circuit according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

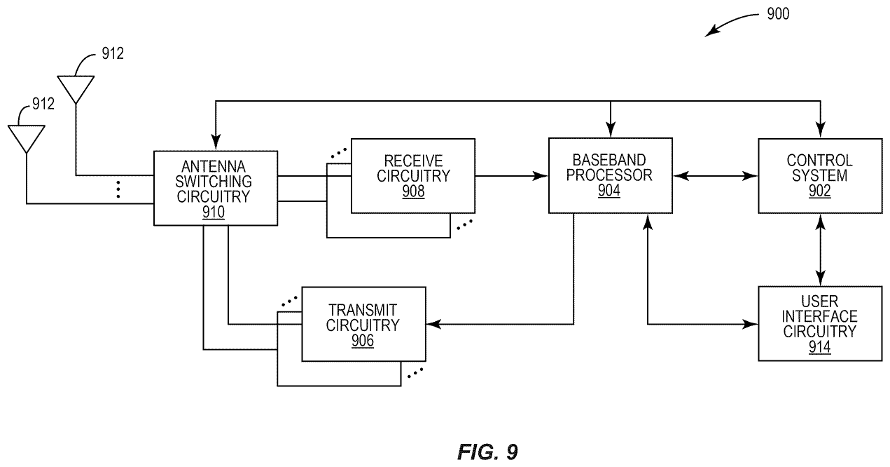

FIG. 9 is a schematic diagram of an exemplary communication device 900 wherein the diode-based bias circuit can be provided. Herein, the communication device 900 can be any type of communication device, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 900 will generally include a control system 902, a baseband processor 904, transmit circuitry 906, receive circuitry 908, antenna switching circuitry 910, multiple antennas 912, and user interface circuitry 914. In a non-limiting example, the control system 902 can be a field-programmable gate array (FPGA) or an application-specific integrated circuit (ASIC), as an example. In this regard, the control system 902 can include at least a microprocessor(s), an embedded memory circuit(s), and a communication bus interface(s). The receive circuitry 908 receives radio frequency signals via the antennas 912 and through the antenna switching circuitry 910 from one or more base stations. A low noise amplifier that may use the diode-based bias circuit of the present disclosure and a filter of the receive circuitry 908 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 904 processes the digitized received signal to extract the information or data bits conveyed in the received signal. This processing typically comprises demodulation, decoding, and error correction operations. The baseband processor 904 is generally implemented in one or more digital signal processors (DSPs) and ASICs.

For transmission, the baseband processor 904 receives digitized data, which may represent voice, data, or control information, from the control system 902, which it encodes for transmission. The encoded data is output to the transmit circuitry 906, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 912 through the antenna switching circuitry 910 to the antennas 912. The multiple antennas 912 and the replicated transmit and receive circuitries 906, 908 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A bias circuit comprising:
a core circuit comprising:
a first diode;
a second diode paired to the first diode;
a resistor, where a voltage difference between the first diode and the second diode appears across the resistor;
a pair of differential field effect transistors (FETs), each of the pair coupled to a respective one of the first and second diodes, at least one of the pair configured to create a feedback signal to an output FET.

2. The bias circuit of claim 1, further comprising a supply voltage at or below 1.5 volts.

3. The bias circuit of claim 1 configured to have a settle time of less than 250 nanoseconds.

4. The bias circuit of claim 1, further comprising a current mirror coupled to one of the pair of differential FETs, wherein the current mirror comprises a first FET and a second diode-connected FET.

5. The bias circuit of claim 4, further comprising a voltage source and a third FET, the third FET connected to the current mirror, the voltage source, and the one of the pair of differential FETs.

6. The bias circuit of claim 5, wherein the voltage source tracks a supply voltage source.

7. The bias circuit of claim 6, further comprising a diode-connected FET coupled to a second one of the pair of differential FETs.

8. The bias circuit of claim 1, further comprising a band gap circuit coupling the first diode and the second diode.

9. The bias circuit of claim 8, wherein the band gap circuit comprises a pair of resistors coupled to respective ones of the first diode and the second diode and a short circuit between the pair of resistors.

10. A wireless transceiver comprising:
a receiver chain comprising:
a low noise amplifier (LNA); and
a bias circuit for the LNA, the bias circuit comprising:
a core circuit comprising:
a first diode;
a second diode paired to the first diode;
a resistor, where a voltage difference between the first diode and the second diode appears across the resistor;
a pair of differential field effect transistors (FETs), each of the pair coupled to a respective one of the first and second diodes, at least one of the pair configured to create a feedback signal to an output FET coupled to the LNA.

11. The wireless transceiver of claim 10, further comprising a supply voltage at or below 1.5 volts.

12. The wireless transceiver of claim 10 configured to have a settle time of less than 250 nanoseconds.

13. The wireless transceiver of claim 10, further comprising a current mirror coupled to one of the pair of differential FETs, wherein the current mirror comprises a first FET and a second diode-connected FET.

14. The wireless transceiver of claim 13, further comprising a voltage source and a third FET, the third FET connected to the current mirror, the voltage source, and the one of the pair of differential FETs.

15. The wireless transceiver of claim 14, wherein the voltage source tracks a supply voltage source.

16. The wireless transceiver of claim 15, further comprising a diode-connected FET coupled to a second one of the pair of differential FETs.

17. The wireless transceiver of claim 10 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

18. A method of controlling a bias circuit, comprising:
providing a supply voltage below 1.5 volts to a pair of diodes in such a manner that a voltage difference therebetween appears across a resistor; and
coupling a differential pair of transistors to the pair of diodes to create a feedback signal that causes the bias circuit to settle in less than 250 nanoseconds.

19. The method of claim 18, further comprising using a current mirror coupled of one of the differential pair of transistors.

20. The method of claim 18, further comprising providing a band gap reference voltage with the bias circuit.
